(19) United States
(12) Patent Application Publication
(10) Pub. No.: US 2026/0197995 A1
(43) Pub. Date: Jul. 9, 2026

(54) BIT CONTACT LANDING AREA

(71) Applicant: Micron Technology, Inc., Boise, ID (US)

(72) Inventors: Protyush SAHU, Boise, ID (US); Jordan D. GREENLEE, Boise, ID (US); Silvia BORSARI, Boise, ID (US); Andrew L. LI, Boise, ID (US); Durai Vishak Nirmal RAMASWAMY, Boise, ID (US)

(21) Appl. No.: 19/392,470

(22) Filed: Nov. 18, 2025

Related U.S. Application Data
(60) Provisional application No. 63/742,134, filed on Jan. 6, 2025.

(51) Int. Cl. H10B 12/00; H10D 62/83; H10W 20/41

(52) U.S. Cl. CPC H10B 12/485; H10B 12/05; H10B 12/482; H10B 12/488; H10D 62/83; H10W 20/435

(57) ABSTRACT

Implementations described herein relate to various structures, integrated assemblies, and memory devices. In some implementations, an integrated assembly may include a first semiconductor pillar and a second semiconductor pillar on a semiconductor substrate. The integrated assembly may further include gate oxide material in an isolation region between the first semiconductor pillar and the second semiconductor pillar, the gate oxide material abutting one or more lower sidewalls of the first semiconductor pillar and the second semiconductor pillar. The integrated assembly may further include a socket structure abutting an upper sidewall of the first semiconductor pillar, and the socket structure abutting an upper surface of the first semiconductor pillar.

### CROSS-REFERENCE TO RELATED APPLICATION

This Patent Application claims priority to U.S. Provisional Patent Application No. 63/742,134, filed on January 6, 2025, entitled “IMPROVED BIT CONTACT LANDING AREA,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to improved bit contact landing area.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a diagrammatic view of an example memory device.

FIG. 2 is a circuit diagram of an example memory cell.

FIG. 3 is a diagrammatic view of an example structure described herein. FIG. 3 includes a top-down view of the structure.

FIGS. 4A and 4B are diagrammatic views of an example structure described herein. FIG. 4A includes a cross-sectional view of the structure and FIG. 4B includes an isometric view of the structure.

FIGS. 5A through 5H are diagrammatic views showing formation of the structure at example process stages of an example process of forming the structure.

FIGS. 6A through 6C are diagrammatic views showing formation of the structure at example process stages of an example process of forming the structure.

FIG. 7 is a flowchart of an example method of forming an integrated assembly or memory device having an improved bit contact landing area.

### DETAILED DESCRIPTION

Manufacturing processes for memory devices, such as DRAM, may include forming an array of one or more semiconductor pillars. The array may include a first semiconductor pillar configured as a bit contact pillar and may couple to a digit line using a bit contact between the digit line and the bit contact pillar. The array may also include a second semiconductor pillar configured as a cell contact pillar and may couple to a capacitor of a memory cell using a cell contact. The bit contact and the cell contact may form respective terminals of a transistor of the memory cell.

Manufacturing processes may further include forming a digit line on the bit contact (e.g., the digit line may land on the bit contact). To mitigate the likelihood of manufacturing defects associated with forming the digit line, the size (e.g., the landing area, the surface area of the interface between the digit line and the bit contact) of the bit contact may be enlarged. Some manufacturing processes may form the array of semiconductor pillars by etching one or more trenches in a semiconductor substrate. These processes may then epitaxially grow semiconductor material, such as silicon, n-type silicon (e.g., phosphorus-doped silicon), silicon carbide, and/or silicon-germanium, among other examples, on the array of semiconductor pillars to increase the size of the semiconductor pillars, and thus increase the size of the bit contact. However, such processes may also increase the size of the cell contact, which may degrade performance of the memory cell capacitor and/or the memory cell transistors. Further, these processes may not provide a physical stopping point for the epitaxial growth, which may result in surface defects such as uneven growth of semiconductor material, bulges, and/or depressions, among other examples.

Some implementations described herein enable selectively increasing the active area of the bit contact. For example, a manufacturing process may include etching a set of trenches in a semiconductor substrate to define one or more semiconductor pillars, including a bit contact pillar and a cell contact pillar. The process may further include forming portions of a memory array, such as a gate oxide abutting one or more sidewalls of the bit contact pillar and one or more sidewalls of the cell contact pillar. The process may further include forming a word line between the bit contact pillar and the cell contact pillar. The process may further include depositing a dielectric material between the bit contact pillar and the cell contact pillar to fill the one or more trenches.

The manufacturing process may include forming a socket structure on the bit contact pillar. Forming the socket structure may include masking off the cell contact pillar and selectively removing a portion of the gate oxide material on the bit contact pillar to form one or more cavities. The one or more cavities may expose upper sidewalls of the bit contact pillar, and may expose one or more sidewalls of the dielectric material. In some examples, the process may also include expanding the one or more cavities by removing exposed portions of the dielectric material. Semiconductor material may be deposited to fill the one or more cavities (e.g., using an epitaxial deposition process and/or a polysilicon deposition process), and thus form the socket structure. The socket structure may be a semiconductor and may comprise, consist of, or consist essentially of semiconductive material. The semiconductive material may comprise, consist of, or consist essentially of silicon (e.g., polycrystalline silicon), among other examples. In some implementations, the socket structure comprises, consists of, or consists essentially of silicon, n-type silicon (e.g., phosphorus-doped silicon), silicon carbide, and/or silicon-germanium, among other examples.

By forming the socket structure in the one or more cavities, the socket structure may abut one or more sidewalls of the bit contact pillar and may abut the upper surface of the bit contact pillar. This arrangement may increase the active area of the socket structure (e.g., the size of the interface between the bit contact pillar and the socket structure), which may reduce resistance between the socket structure and the bit contact pillar. Additionally, the increased size of the socket structure may provide an increased landing area for a digit line as part of subsequent manufacturing steps, which may reduce the likelihood of manufacturing defects. Further, masking off the cell contact pillar may allow for independent control of the size of the bit contact landing area without affecting the cell contact.

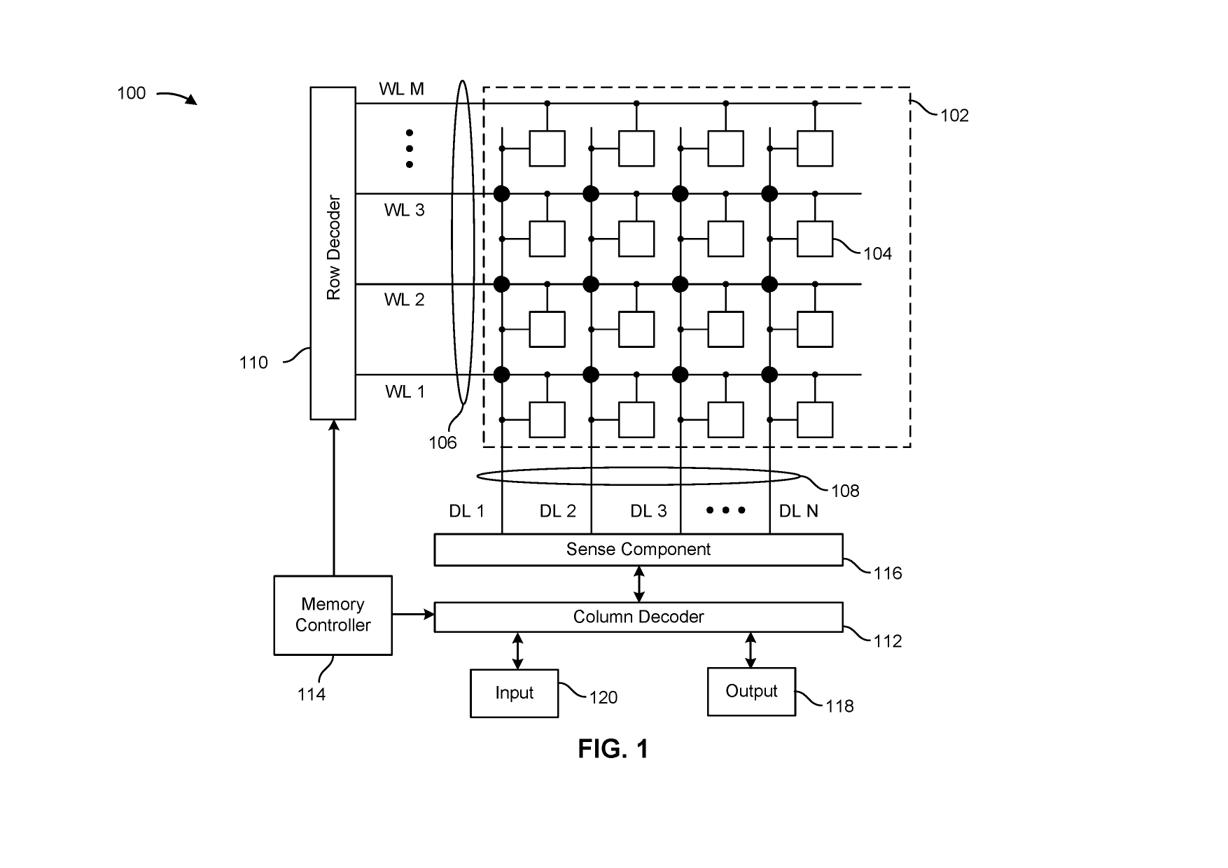

FIG. 1 is a diagrammatic view of an example memory device 100. The memory device 100 may include a memory array 102 that includes multiple memory cells 104. A memory cell 104 is programmable or configurable into a data state of multiple data states (e.g., two or more data states). For example, a memory cell 104 may be set to a particular data state at a particular time, and the memory cell 104 may be set to another data state at another time. A data state may correspond to a value stored by the memory cell 104. The value may be a binary value, such as a binary 0 or a binary 1, or may be a fractional value, such as 0.5, 1.5, or the like. A memory cell 104 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 104 by activating or selecting the appropriate word line 106 (shown as access lines WL 1 through WL M) and digit line 108 (shown as digit lines DL 1 through DL N). A word line 106 may also be referred to as a “row line” or an “access line,” and a digit line 108 may also be referred to as a “column line” or a “bit line.” Activating or selecting a word line 106 or a digit line 108 may include applying a voltage to the respective line. A word line 106 and/or a digit line 108 may comprise, consist of, or consist essentially of a conductive material, such as a metal (e.g., copper, aluminum, gold, titanium, or tungsten) and/or a metal alloy, among other examples. In FIG. 1, each row of memory cells 104 is connected to a single word line 106, and each column of memory cells 104 is connected to a single digit line 108. By activating one word line 106 and one digit line 108 (e.g., applying a voltage to the word line 106 and digit line 108), a single memory cell 104 may be accessed at (e.g., is accessible via) the intersection of the word line 106 and the digit line 108. The intersection of the word line 106 and the digit line 108 may be called an “address” of a memory cell 104.

In some implementations, the logic storing device of a memory cell 104, such as a capacitor, may be electrically isolated from a corresponding digit line 108 by a selection component, such as a transistor. The word line 106 may be connected to and may control the selection component. For example, the selection component may be a transistor, and the word line 106 may be connected to the gate of the transistor. Activating the word line 106 results in an electrical connection or closed circuit between the capacitor of a memory cell 104 and a corresponding digit line 108. The digit line 108 may then be accessed (e.g., is accessible) to either read from or write to the memory cell 104.

A row decoder 110 and a column decoder 112 may control access to memory cells 104. For example, the row decoder 110 may receive a row address from a memory controller 114 and may activate the appropriate word line 106 based on the received row address. Similarly, the column decoder 112 may receive a column address from the memory controller 114 and may activate the appropriate digit line 108 based on the column address.

Upon accessing a memory cell 104, the memory cell 104 may be read (e.g., sensed) by a sense component 116 to determine the stored data state of the memory cell 104. For example, after accessing the memory cell 104, the capacitor of the memory cell 104 may discharge onto its corresponding digit line 108. Discharging the capacitor may be based on biasing, or applying a voltage, to the capacitor. The discharging may induce a change in the voltage of the digit line 108, which the sense component 116 may compare to a reference voltage (not shown) to determine the stored data state of the memory cell 104. For example, if the digit line 108 has a higher voltage than the reference voltage, then the sense component 116 may determine that the stored data state of the memory cell 104 corresponds to a first value, such as a binary 1. Conversely, if the digit line 108 has a lower voltage than the reference voltage, then the sense component 116 may determine that the stored data state of the memory cell 104 corresponds to a second value, such as a binary 0. The detected data state of the memory cell 104 may then be output (e.g., via the column decoder 112) to an output component 118 (e.g., a data buffer). A memory cell 104 may be written (e.g., set) by activating the appropriate word line 106 and digit line 108. The column decoder 112 may receive data, such as input from input component 120, to be written to one or more memory cells 104. A memory cell 104 may be written by applying a voltage across the capacitor of the memory cell 104.

The memory controller 114 may control the operation (e.g., read, write, re-write, refresh, and/or recovery) of the memory cells 104 via the row decoder 110, the column decoder 112, and/or the sense component 116. The memory controller 114 may generate row address signals and column address signals to activate the desired word line 106 and digit line 108. The memory controller 114 may also generate and control various voltages used during the operation of the memory array 102.

In some implementations, the memory device 100 may include one or more semiconductor pillars, such as one or more cell contact pillars and/or one or more bit contact pillars. A cell contact pillar and bit contact pillar may act as a transistor to selectively couple the capacitor of a memory cell to a digit line 108. As described in greater detail elsewhere herein, the bit contact pillar may couple to the digit line 108 using a socket structure. The socket structure may abut an upper surface of the bit contact pillar and may abut one or more sidewalls of the bit contact pillar. The socket structure may provide an improved connection between the digit line and the bit contact pillar, such as by reducing the resistance thereof. Further, the socket structure may provide an increased landing area for the digit line, and thus reduce the likelihood of manufacturing defects associated with manufacturing the memory device 100.

In some implementations, the memory device 100 includes the structure 400 and/or an integrated assembly that includes the structure 400. For example, the memory array 102 may include the structure 400 and/or an integrated assembly that includes the structure 400. Additionally, or alternatively, the memory cell 104 may include a memory cell described elsewhere herein.

As indicated above, FIG. 1 is provided as an example. Other examples may differ from what is described with respect to FIG. 1.

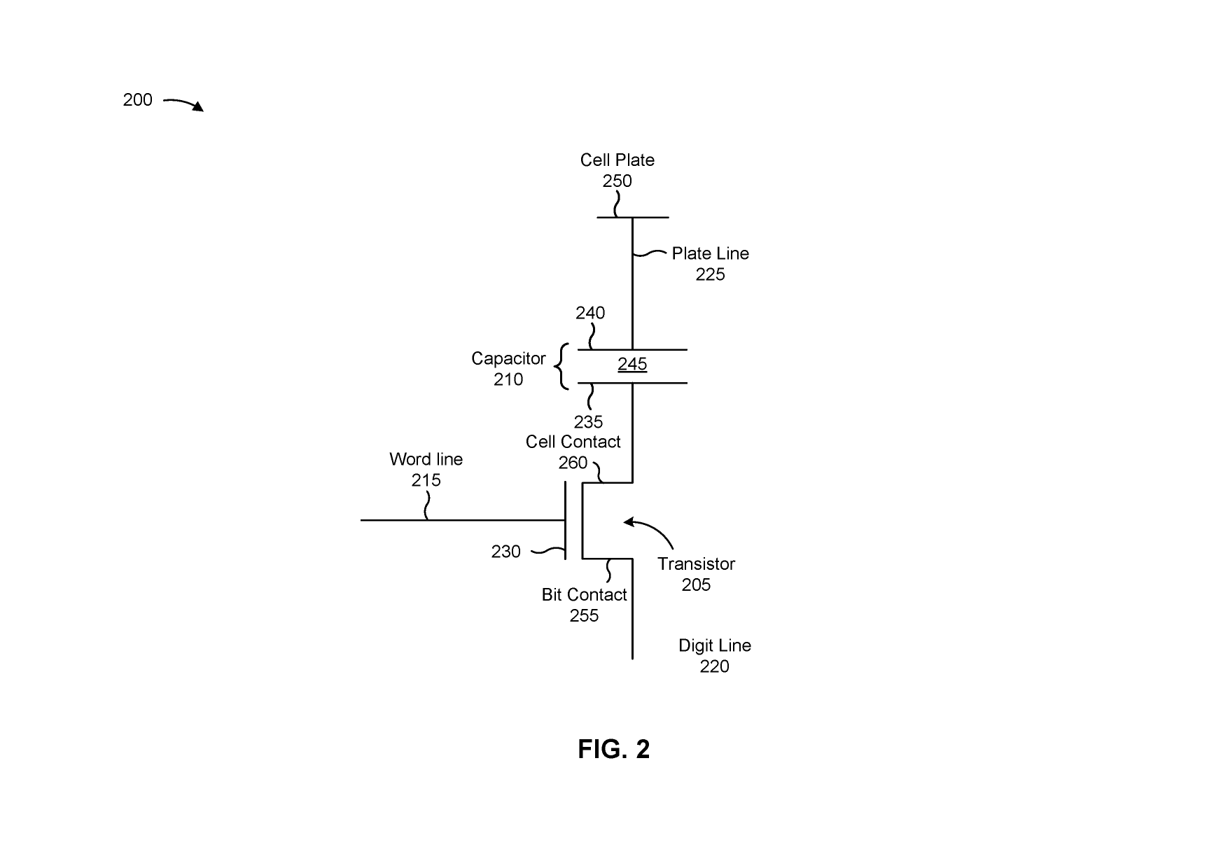

FIG. 2 is a circuit diagram of an example memory cell 200. In some implementations, the memory cell 200 is a ferroelectric memory cell. Alternatively, the memory cell 200 may be a linear dielectric memory cell or a paraelectric memory cell.

As shown in FIG. 2, the memory cell 200 may include a transistor 205 (or another type of selection circuit) and a capacitor 210. The memory cell 200 may be accessed (e.g., written to, read from, and/or erased) using signals on a combination of lines that are coupled to the memory cell 200, shown as a word line 215 (sometimes called an “access line”), a digit line 220 (sometimes called a “bit line”), and a plate line 225.

The transistor 205 (sometimes called an access transistor) may include a gate 230. The capacitor 210 includes a bottom electrode 235 and a top electrode 240 separated by an insulator 245. In some implementations, the capacitor is a ferroelectric capacitor, and the insulator 245 is a ferroelectric insulator that comprises, consists of, or consists essentially of ferroelectric material. Alternatively, the capacitor may be a linear dielectric capacitor, and the insulator 245 may be a linear dielectric insulator that comprises, consists of, or consists essentially of linear dielectric material. Alternatively, the capacitor may be a paraelectric capacitor, and the insulator 245 may be a paraelectric insulator that comprises, consists of, or consists essentially of paraelectric material. When the word line 215 is activated (e.g., when a voltage is applied to the word line 215), the gate 230 coupled to the word line 215 may be activated. When the gate 230 is activated, the transistor 205 couples the digit line 220 to the bottom electrode 235 of the capacitor 210. A state of the memory cell 200 may then be written or read via the digit line 220.

The top electrode 240 of the capacitor 210 may be coupled to the plate line 225 and a cell plate 250. To write to (or program) the memory cell 200, the word line 215 may be activated, and a voltage may be applied across the capacitor 210 by controlling the voltage of the top electrode 240 (via the plate line 225 and/or the cell plate 250) and/or the bottom electrode 235 (via the digit line 220).

For a ferroelectric capacitor, the applied voltage creates an electric field, and the atoms in the ferroelectric material of the insulator 245 respond to the electric field to become arranged in a particular state (e.g., a particular orientation or polarization), which is representative of a data state (e.g., a logic “0” state or a logic “1” state). In some implementations, data may be stored using the capacitor 210 by controlling a voltage difference and/or a polarity difference of the capacitor 210 (e.g., of the insulator 245 between the bottom electrode 235 and the top electrode 240). For example, a voltage of the cell plate 250 and the digit line 220 may be controlled. In some implementations, a negative polarity of the insulator 245 as compared to the cell plate 250 results in a logic “0” state being stored in the capacitor 210, and a positive polarity of the insulator 245 as compared to the cell plate 250 results in a logic “1” state being stored in the capacitor 210. For a linear dielectric capacitor or a paraelectric capacitor, the cell plate 250 may be grounded, and the capacitor 210 may be charged by applying a voltage to the bottom electrode 235 via the digit line 220.

To read the memory cell 200 (e.g., a state stored by the capacitor 210), the word line 215 may be activated, and a voltage may be applied to the plate line 225. Applying a voltage to the plate line 225 may cause a change in the stored charge on the capacitor 210. The magnitude of the change in stored charge may depend on the stored state of capacitor 210 (e.g., whether the stored state is a logic “1” state or a logic “0” state). This may or may not induce a threshold change in the voltage of the digit line 220 based on the charge stored on the capacitor 210. The change in voltage or lack of change in voltage of the digit line 220 (or a magnitude of the change in voltage) may be used to determine the stored state of the capacitor 210. For example, if the change in voltage satisfies a threshold, then the read operation indicates that a first state was stored in the capacitor 210, whereas if the change in voltage does not satisfy the threshold, then the read operation determines that a second state was stored in the capacitor 210. In some cases, multiple threshold voltages may be used, such as when the capacitor is capable of storing more than two data states (e.g., for a multi-level cell, a triple-level cell, and so on).

In some implementations, the transistor 205 may include a bit contact 255, a cell contact 260, and one or more semiconductor pillars extending vertically from a semiconductor substrate. The cell contact 260 may be part of a connection between the transistor 205 and the capacitor 210. For example, the cell contact 260 may include doped semiconductor material (e.g., n-type doped semiconductor material, p-type doped semiconductor material, and/or an allowed semiconductor material, such as silicon-germanium and/or silicon carbide) coupled with a first semiconductor pillar (e.g., a cell contact pillar) of the one or more semiconductor pillars, and may form a first terminal of the transistor 205. The bit contact 255 may be part of a connection between the transistor 205 and the digit line 220. For example, the bit contact 255 may include doped semiconductor material (e.g., n-type doped semiconductor material or p-type doped semiconductor material) coupled with a second semiconductor pillar (e.g., a bit contact pillar) of the one or more semiconductor pillars, and may form a second terminal of the transistor 205. Thus, the cell contact 260 may be used as the source terminal of the transistor 205, the bit contact 255 may be used as the drain terminal of the transistor 205, and the one or more semiconductor pillars may be used as a channel region of the transistor 205. As described in greater detail elsewhere herein, the bit contact 255 may include a socket structure. The socket structure may abut an upper surface of the bit contact pillar and may abut one or more sidewalls of the bit contact pillar. The socket structure may provide an improved connection between the digit line and the bit contact pillar, such as by reducing the resistance thereof. Further, the socket structure may provide an increased landing area for the digit line, and thus reduce the likelihood of manufacturing defects associated with manufacturing the memory cell 200.

As indicated above, FIG. 2 is provided as an example. Other examples may differ from what is described with respect to FIG. 2.

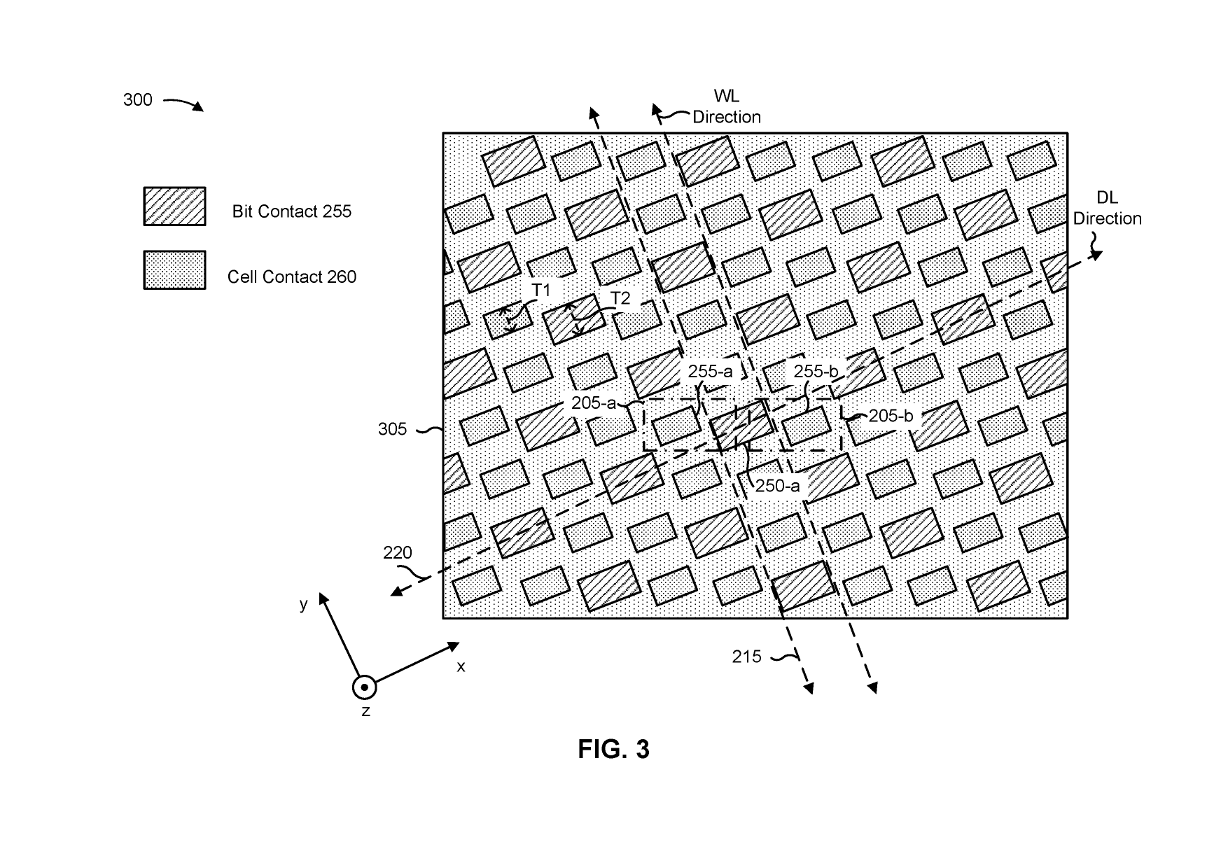

FIG. 3 is a top-down diagrammatic view of an example structure 300. The structure 300 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). The structure 300 may be associated with a manufacturing step of manufacturing a memory device. Subsequent manufacturing steps may alter the structure 300, such as by forming additional layers, removing one or more layers of the structure 300, and/or modifying one or more components of the structure 300, among other examples.

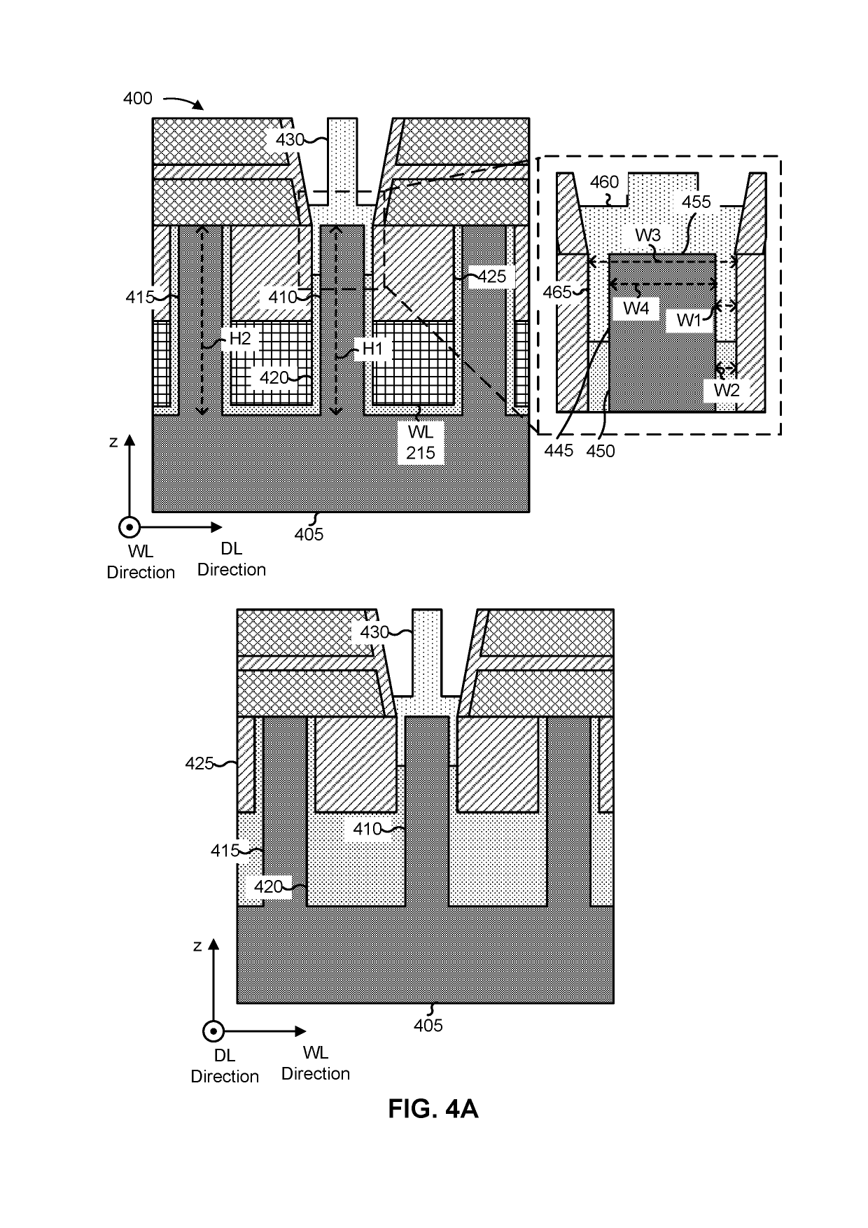

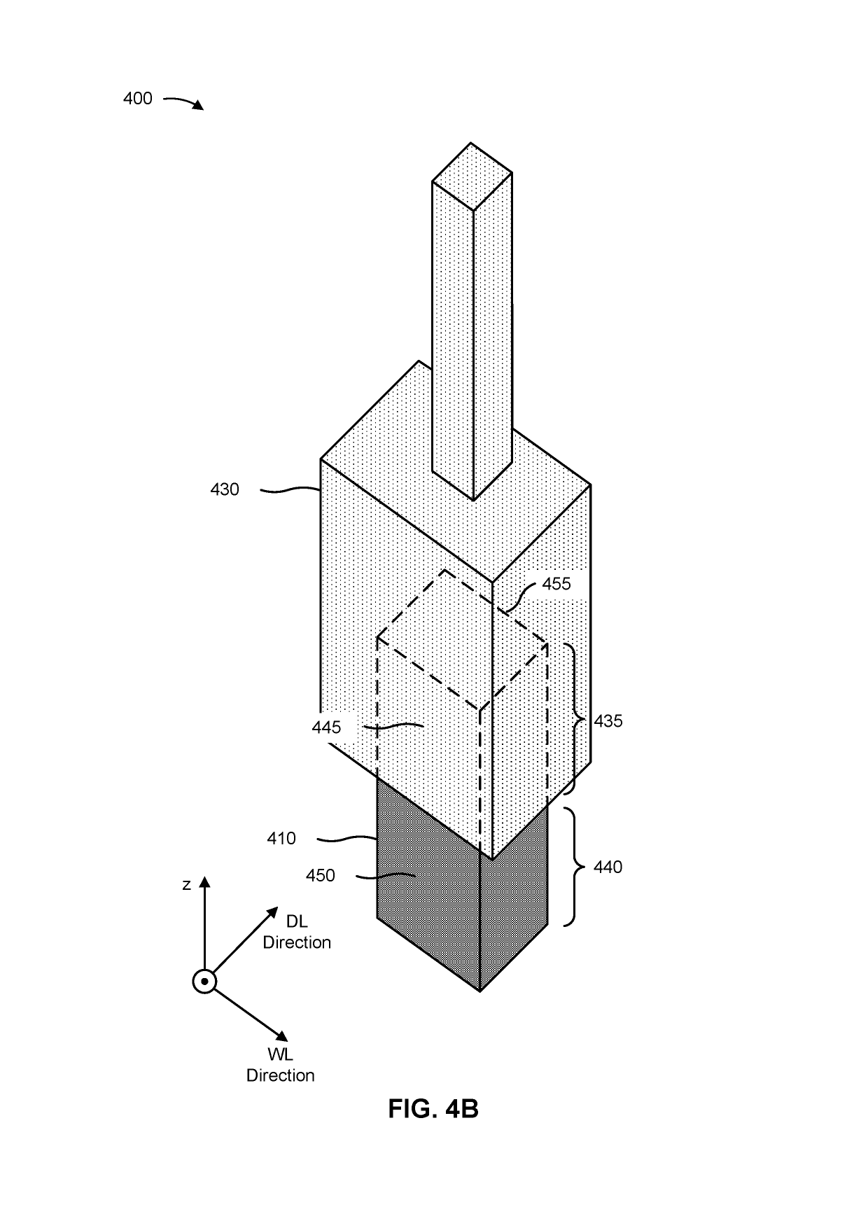

The structure 300 may be part of or may include aspects of a memory array 102. For example, the structure 300 may include one or more bit contacts 255 and one or more cell contacts 260 arranged in a grid-like structure. A bit contact 255 may couple to an upper surface of a first semiconductor pillar (e.g., a bit contact pillar, as described in greater detail in connection to FIG. 4A) extending vertically from a semiconductor substrate. A cell contact 260 may couple to an upper surface of a second semiconductor pillar (e.g., a bit contact pillar, as described in greater detail in connection to FIG. 4A) extending vertically from a semiconductor substrate. In some examples, the structure 300 may include a dielectric material 305 extending between the one or more bit contacts 255 and the one or more cell contacts 260, which may provide structural support to the structure 300 and/or may isolate the one or more bit contacts 255 and the one or more cell contacts 260.

The structure 300 may include one or more word lines 215 extending in a first horizontal direction (e.g., a word line direction). In some cases, the first horizontal direction may align with a crystal orientation of the semiconductor substrate. For example, the first horizontal direction may correspond to or be based on the (100) direction, the (110) direction, and/or the (111) direction of the semiconductor substrate, among other examples. The one or more word lines 215 may be positioned beneath the bit contacts 255 and the cell contacts 260 (e.g., between a bit contact 255 and the semiconductor substrate), as described in greater detail in connection with FIG. 4A. In some examples, the structure 300 may include, or subsequent manufacturing operations may form, one or more digit lines 220 extending in a second horizontal direction (e.g., a digit line direction) approximately perpendicular to the first horizontal direction.

The bit contacts 255, the cell contacts 260, and the word lines 215 may form one or more transistors 205. For example, a cell contact 260 may act as a source terminal of a transistor 205, a bit contact 255 may act as a drain terminal of the transistor 205, and a word line 215 may act as the gate of the transistor 205. Accordingly, activating the word line 215 may allow current to flow from a capacitor 210 coupled to the cell contact 260 to a digit line 220 coupled to the bit contact 255. In some examples, a bit contact 255 may be shared between pairs of transistors 205. For example, a first transistor 205-a may include a cell contact 260-a and a bit contact 255-a. A second transistor 205-b may include a cell contact 260-b and the bit contact 255-a.

As described in greater detail elsewhere herein, a manufacturing process for a memory device that include the structure 300 may support forming a socket structure, which may allow for independent control of the size of the bit contact 255 landing area without affecting the size of the cell contact 260. Accordingly, in some examples, the thickness T1 of a cell contact 260 (e.g., in a horizontal direction, such as the word line direction and/or the digit line direction) may be less than a thickness T2 of a bit contact 255 (e.g., in the horizontal direction). This increased thickness may provide an increased landing area for one or more digit lines 220 formed as part of subsequent manufacturing steps, which may improve the electrical connectivity and/or reduce the contact resistance between a digit line 220 and a bit contact 255. Further, the larger landing area of a bit contact 255 may decrease the likelihood of manufacturing defects associated with forming the digit line 220.

As indicated above, FIG. 3 is provided as an example. Other examples may differ from what is described with regard to FIG. 3.

FIGS. 4A and 4B are diagrammatic views of an example structure 400. The structure 400 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). For example, the structure 400 may be part of or may include aspects of a memory array 102, a memory cell 104, and/or a memory cell 200. The structure 400 may be associated with a manufacturing step of manufacturing a memory device. Subsequent manufacturing steps may alter the structure 400, such as by forming additional layers, removing one or more layers of the structure 400, and/or modifying one or more components of the structure 400, among other examples. FIG. 4A illustrates cross-sectional view of the structure 400. FIG. 4B illustrates an isometric view of aspects of the structure 400.

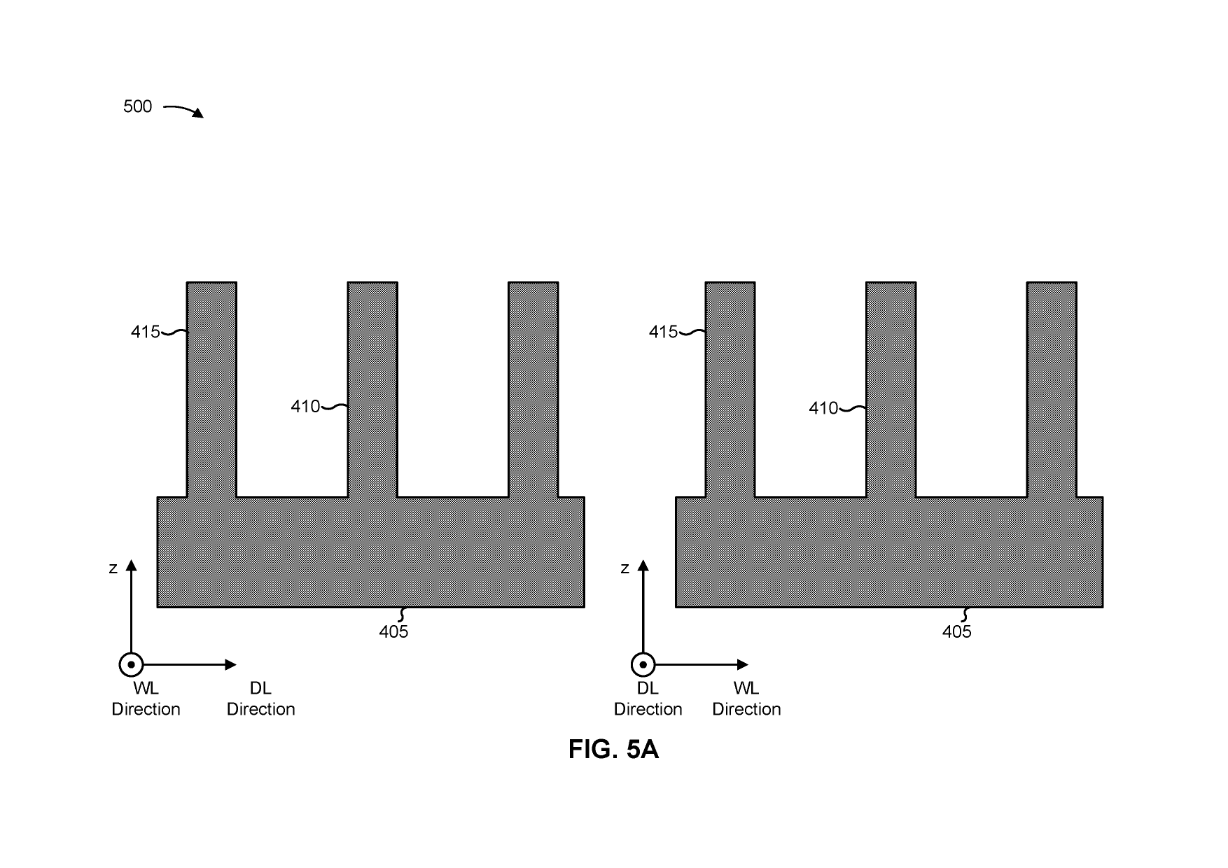

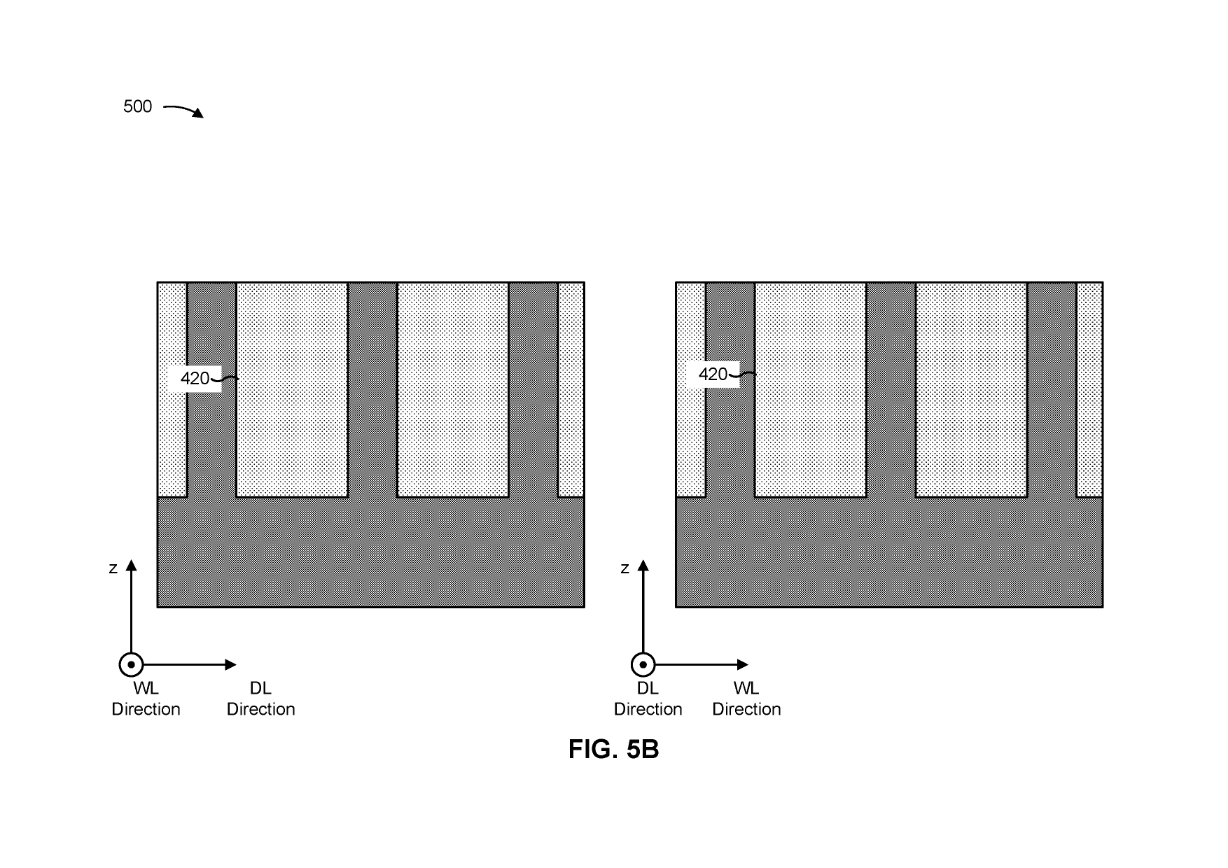

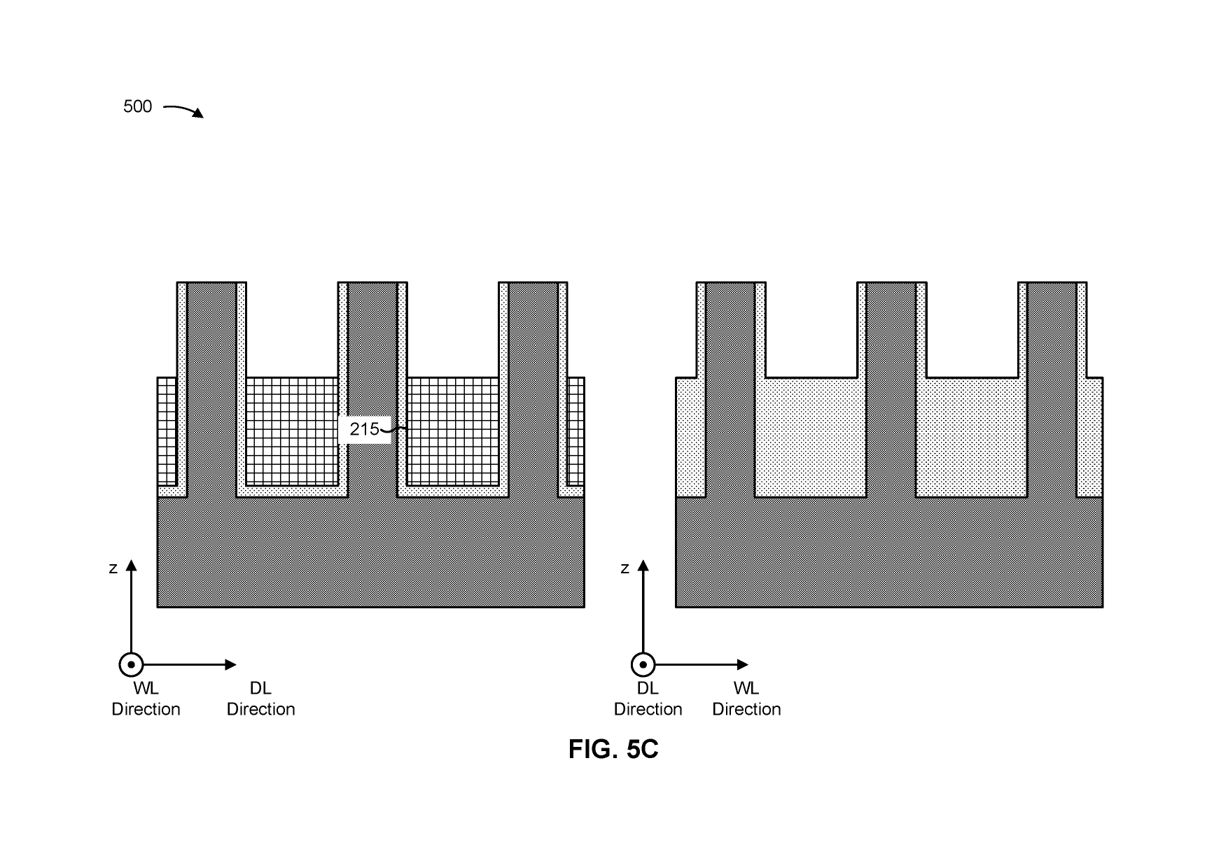

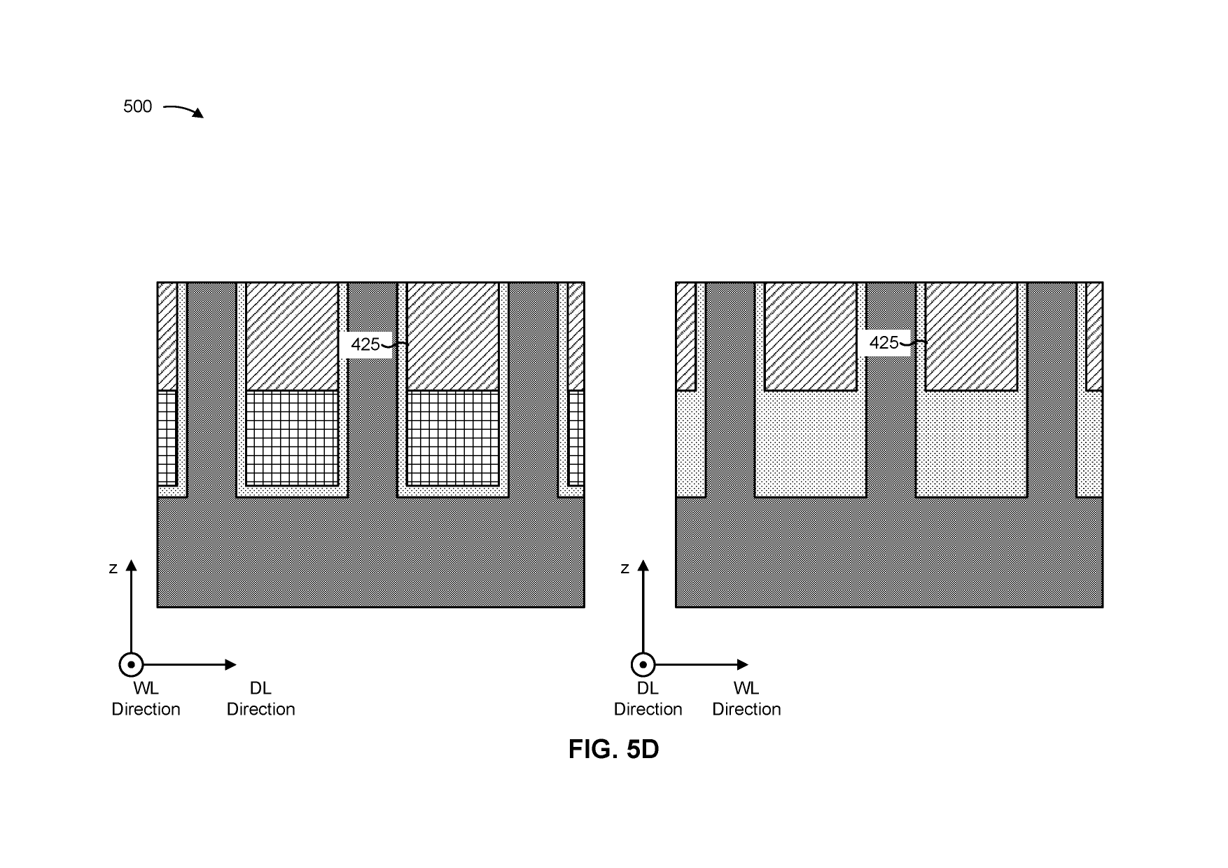

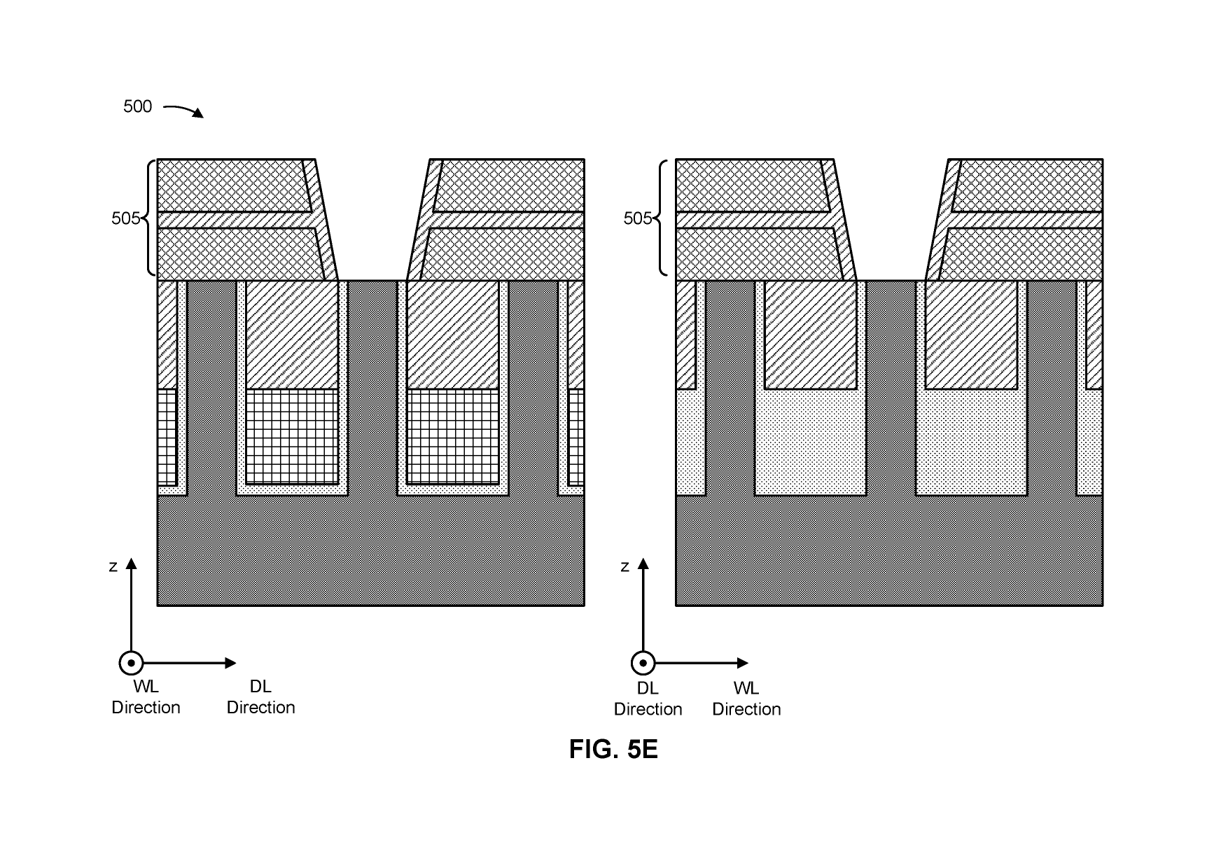

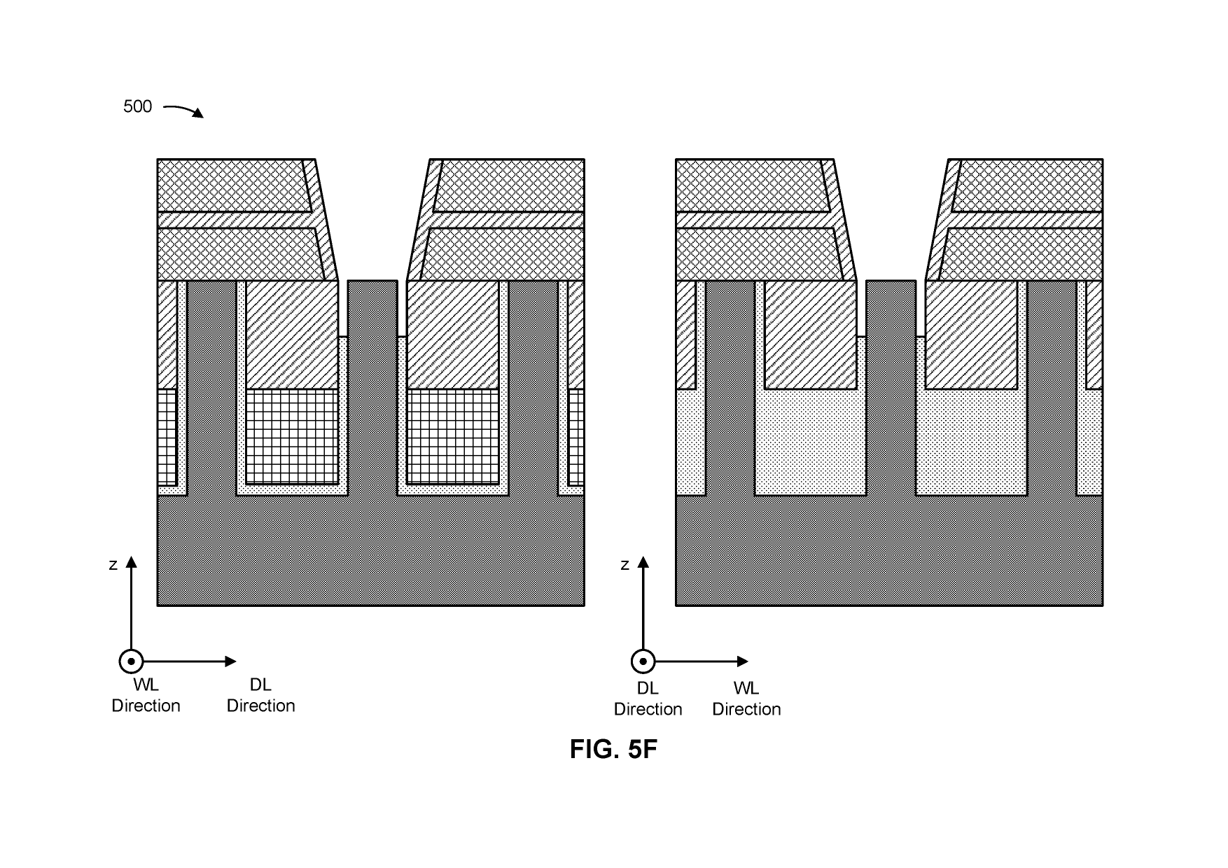

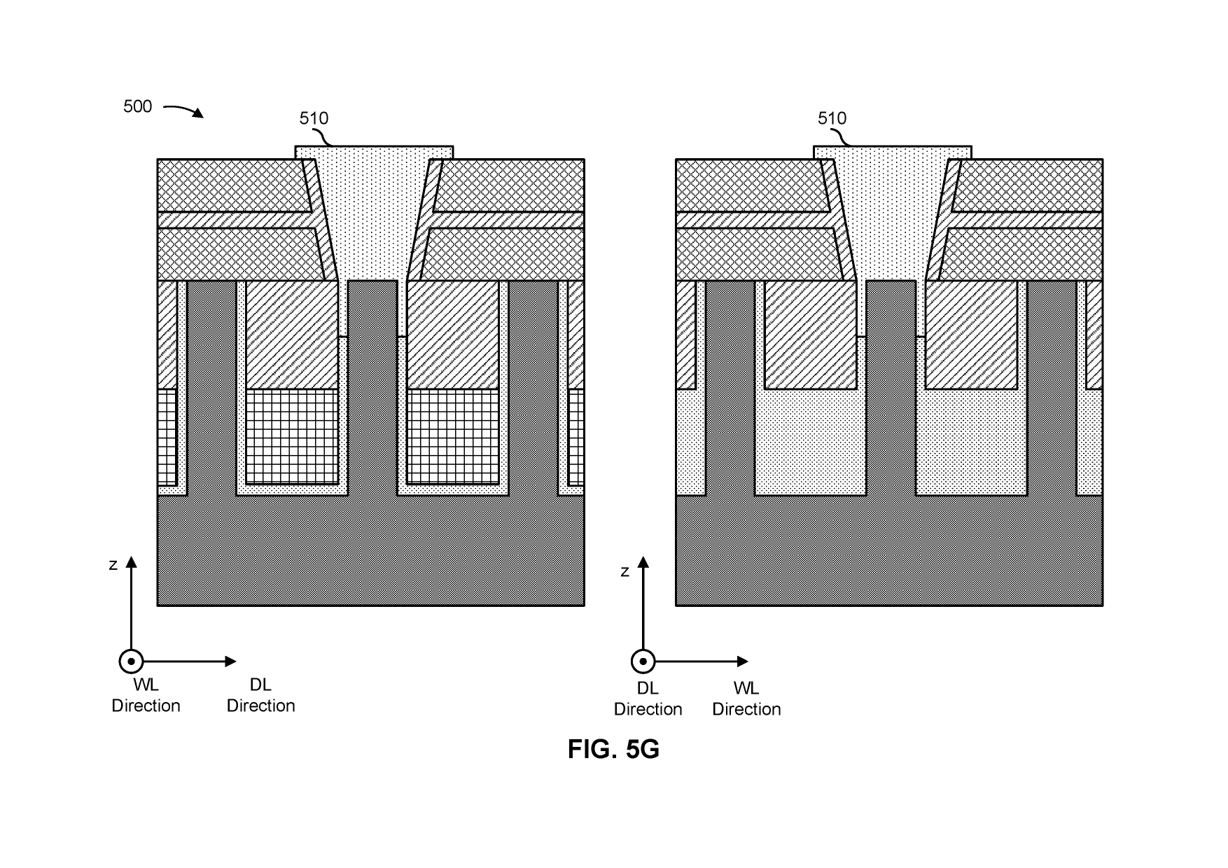

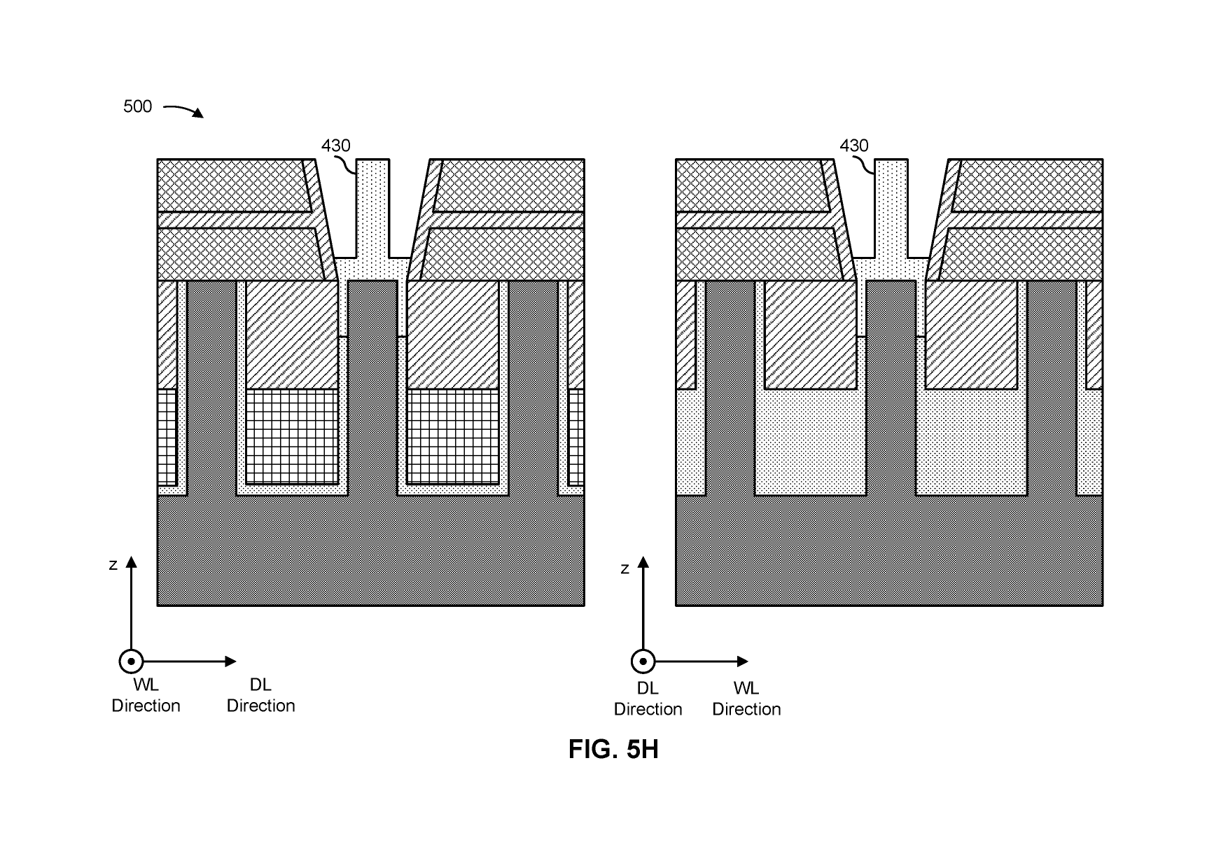

The structure 400 may include one or more components of one or more transistors 205. For example, the structure 400 may include an array of one or more semiconductor pillars. A semiconductor pillar (e.g., each semiconductor pillar) may extend vertically (e.g., in the z-direction) from a semiconductor substrate 405. The semiconductor substrate 405 may be a bulk silicon substrate, a bulk silicon-germanium substrate, and/or a bulk silicon-carbon substrate, among other examples. In some examples, the semiconductor substrate 405 may be doped (e.g., lightly doped) with a p-type or an n-type impurity. As described in greater detail in connection with FIG. 5A, the semiconductor pillars may be formed by etching one or trenches in the semiconductor substrate 405.

The array of one or more semiconductor pillars may include one or more bit contact pillars 410 and one or more cell contact pillars 415. The one or more bit contact pillars 410 and the one or more cell contact pillars 415 may be arranged in a grid structure and may be positioned under one or more bit contacts 255 and one or more cell contacts 260, respectively, as described in greater detail in connection to FIG. 3. A bit contact pillar 410 may be configured to couple to a digit line (e.g., using a bit contact 255), and a cell contact pillar 415 may be configured to couple to a capacitor of a memory cell (e.g., using a cell contact 260). A bit contact pillar 410 may form part of a first terminal (e.g., a drain) and/or a channel of one or more transistors 205. A cell contact pillar 415 may form part of a second terminal (e.g., a drain) and/or a channel of one or more transistors.

The structure 400 may include one or more shallow-trench isolation (STI) regions between adjacent semiconductor pillars. An STI region may include a gate oxide material 420. The gate oxide material 420 may be conformally deposited to abut sidewalls of a bit contact pillar 410, a cell contact pillar 415, and/or a surface of the semiconductor substrate 405 within the STI region. The gate oxide material 420 may be a dielectric material, such as silicon-oxide or other insulating material. The gate oxide material 420 may insulate a gate of a transistor from the bit contact pillar 410, the cell contact pillar 415, and/or the surface of the semiconductor substrate 405 within the STI region.

The structure 400 may include one or more word lines 215 extending in a first horizontal direction (e.g., in a word line direction as shown in FIG. 3). A word line 215 may act as a gate structure for the transistor. A word line 215 may be an electrical conductor and may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples.

In some examples, the structure 400 may include a dielectric material 425, such as silicon oxide and/or silicon nitride, among other examples, in the STI region. The dielectric material 425 may be an insulative material used to isolate adjacent semiconductor pillars and/or provide mechanical support to the structure 400 during manufacturing operations. In some examples, the dielectric material 425 may be a nitride material, such as silicon nitride. In some implementations, the word line 215 and the dielectric material 425 may form a gate structure for a transistor. For example, the gate structure may include a conductive portion (e.g., the word line 215) and a cap portion (e.g., the dielectric material 425) on the conductive portion. In such an example, the gate oxide material 420 may be between the bit contact pillar 410 and the gate structure. The gate oxide material 420 may cover a side surface (e.g., a sidewall) of the conductive portion. Additionally, the gate oxide material 420 may cover a lower side surface (e.g., a lower sidewall) of the cap portion without covering an upper side surface (e.g., an upper sidewall) of the cap portion.

The structure 400 may include a socket structure 430 on the bit contact pillar 410. The socket structure 430 may be or may include aspects of a bit contact (e.g., a bit contact 255) configured to couple the bit contact pillar 410 to a digit line (e.g., a digit line 220) extending in a second horizontal direction (e.g., the digit line direction). As described in greater detail elsewhere herein, the socket structure 430 may be formed without etching the bit contact pillar 410. Accordingly, the height H1 (e.g., in the z-direction) of the bit contact pillar 410 may be approximately equal to the height H2 (e.g., in the z-direction) of a cell contact pillar 415. In some implementations, a portion of the socket structure 430 may protrude downwardly (e.g., along the z-direction) to be between the upper side surface of the cap portion and the bit contact pillar 410.

FIG. 4B shows an enlarged view of the bit contact pillar 410 and the socket structure 430. As illustrated in FIG. 4B, the bit contact pillar 410 may include an upper portion 435 and a lower portion 440 below (e.g., along the z-direction) the upper portion 435. The bit contact pillar 410 may further include one or more upper sidewalls 445 of the upper portion 435 and one or more lower sidewalls 450 of the lower portion 440. Additionally, the bit contact pillar 410 may include an upper surface 455. The socket structure 430 may abut the upper surface 455 of the bit contact pillar 410. Additionally, the socket structure 430 may abut at least a portion of the outer perimeter of the upper portion 435 of the bit contact pillar 410. The socket structure 430 may also surround the upper portion 435 of the bit contact pillar 410 to abut additional upper sidewalls 445.

Referring back to FIG. 4A, the socket structure 430 may include an upper portion 460 and one or more overhangs 465 extending downward from the upper portion 460. The upper portion 460 and the one or more overhangs 465 of the socket structure 430 may form a recess or cavity around the bit contact pillar 410. The upper portion 460 of the socket structure 430 may be in contact with the upper surface 455 of the bit contact pillar 410. Additionally, the one or more overhangs 465 of the socket structure 430 may abut respective upper sidewalls 450 of the bit contact pillar 410. This arrangement of the overhangs 465 and the upper portion 460 may result in a concave profile of the socket structure 430.

Each upper sidewall 445 of the bit contact pillar 410 may abut respective overhangs 465 of the socket structure 430. Alternatively, the socket structure 430 may abut a subset of the upper sidewalls 445 of the bit contact pillar 410. For example, the socket structure 430 may include overhangs 465 that abut upper sidewalls 445 aligned in a first horizontal direction (e.g., the word line direction or the digit line direction) and may not include overhangs 465 that abut upper sidewalls 445 aligned in a second horizontal direction (e.g., the digit line direction or the word line direction).

In some implementations, the width W1 of an overhang 465 of the socket structure 430 may be approximately equal to the width W2 of the gate oxide material 420 (e.g., the thickness of the gate oxide material 420 on sidewalls of the bit contact pillar 410). For example, as described in greater detail in connection with FIGS. 5A through 5H, the socket structure 430 may be formed, in part, by removing one or more portions of the gate oxide material 420 using an etching operation. The etching operation may include selectively etching the gate oxide material 420 to form one or more cavities. Forming the socket structure 430 may further include forming the overhangs 465 by depositing semiconductor material (e.g., n-type semiconductor material) to fill the one or more cavities and forming the upper portion 460 by depositing the semiconductor material above the one or more cavities. Accordingly, the overhangs 465 may align with the gate oxide, resulting in the width W1 being approximately equal to the width W2.

Alternatively, the width W1 of an overhang 465 of the socket structure 430 may be greater than the width W2 of the gate oxide material 420. For example, as described in greater detail in connection with FIGS. 5A through 5H, forming the socket structure 430 may further include removing a portion of the dielectric material 425 to expand the one or more cavities using an additional etching operation. The additional etching operation may include selectively etching the dielectric material 425 exposed by the one or more cavities, thus increasing the size of the one or more cavities. Accordingly, forming the one or more overhangs 465 in the one or more cavities may result in overhangs 465 that extend, in a horizontal direction, beyond the gate oxide material 420 (e.g., that extend over at least a portion of the dielectric material 425).

Because the socket structure 430 may, at least partially, surround the upper portion 435 of the bit contact pillar 410, the overall width W3 of the socket structure 430 (e.g., in a horizontal direction, such as the word line direction and/or the digit line direction) may be greater than the width W4 of the bit contact pillar 410 (e.g., in the horizontal direction). The greater width W3 may result in a “bulge” of semiconductor material at and/or around the interface of the socket structure 430 and the bit contact pillar 410 (e.g., due to the one or more overhangs 465), and may thus increase the landing area for a digit line. Further, this bulge may be detectable using imaging techniques such as transmission electron microscopy (TEM), high-resolution TEM (HRTEM), and/or scanning electron microscopy (SEM), among other examples. Additionally, because the chemical makeup of the socket structure 430 may differ from the chemical makeup of the bit contact pillar 410 (e.g., the socket structure 430 may have an increased concentration of n-type dopants such as phosphorous, arsenic, and/or antimony), the bulge may be detectable using chemical signature analysis from the socket structure 430, such as energy-dispersive X-ray spectroscopy (EDS).

Each of the illustrated axes (e.g., in the word line direction, the digit line direction, and the z-direction) are substantially perpendicular to the other two axes. In other words, the word line direction is substantially perpendicular to the digit line direction and the z-direction, the digit line direction is substantially perpendicular to the word line direction and the z-direction, and the z-direction is substantially perpendicular to the word line direction and the digit line direction. In some cases, a single reference number is shown to refer to a surface, or fewer than all instances of a part may be labeled with all surfaces of that part. All instances of the part may include associated surfaces of that part despite not every surface being labeled.

As indicated above, FIGS. 4A and 4B are provided as examples. Other examples may differ from what is described with regard to FIGS. 4A and 4B.

FIGS. 5A through 5H are diagrammatic views showing formation of the structure 400 at example process stages of an example process 500 of forming the structure 400. In some implementations, the example process described below in connection with FIGS. 5A through 5H may correspond to the method 700 and/or one or more blocks of the method 700. However, the process described below is an example, and other example processes may be used to form the structure 400, an integrated assembly that includes the structure 400, and/or one or more parts of the structure 400 and/or the integrated assembly.

As shown in FIG. 5A, the process 500 may include forming the one or more semiconductor pillars, such as one or more bit contact pillars 410 and/or one or more cell contact pillars 415, in the semiconductor substrate 405. In some cases, the one or more semiconductor pillars may be formed using STI techniques (e.g., the one or more semiconductor pillars may be STI pillars). For example, the process 500 may include removing (e.g., etching) one or more portions of the semiconductor substrate to form one or more trenches. A trench may expose one or more sidewalls of a semiconductor pillar. Said another way, the one or more trenches may define the one or more semiconductor pillars.

Forming the one or more trenches may include forming a masking material, such as a hard mask oxide material, over portions of the semiconductor substrate. A photoresist material may be deposited (e.g., spin-coated) onto the masking material and exposed to radiation to form a pattern in the photoresist material. A developer may be used to remove portions to reveal the pattern, and the masking material may be etched to transfer the pattern to the masking material. The pattern in the masking material may then be used to etch the semiconductor substrate and define the semiconductor pillars, for example by using a plasma-based etch. In some examples, after forming the one or more trenches, the masking material may be removed, for example by using a wet etchant selective to the masking material.

As shown in FIG. 5B, the process 500 may include forming the gate oxide material 420. In some examples, forming the gate oxide material 420 may include conformally depositing the gate oxide material on sidewalls of a bit contact pillar 410 (e.g., on lower sidewalls 450 and/or upper sidewalls 445), sidewalls of a cell contact pillars 415, and the surface of the semiconductor substrate 405 between the bit contact pillar 410 and the cell contact pillar 415 (e.g., within the STI region). The gate oxide material 420 may comprise, consist of, or consist essentially of a dielectric material, such as silicon oxide and/or other insulating materials. The conformal deposition process may include techniques such as thermal oxidation, chemical vapor deposition (CVD) and/or atomic layer deposition (ALD), among other examples. The conformal deposition process may leave the one or more trenches between bit contact pillars 410 and cell contact pillars 415 partially unfilled. The process 500 may include filling the one or more trenches as part of subsequent processing steps.

As shown in FIG. 5C, the process 500 may include forming one or more word lines 215 in STI regions of the structure 400. Forming the one or more word lines 215 may include depositing a conductive material, such as a metal (e.g., tungsten, titanium, or cobalt) or a conductively-doped semiconductor material (e.g., conductively-doped silicon), using a deposition process, such as CVD or physical vapor deposition (PVD). The conductive material may be deposited to be abutting the gate oxide material 420, such that the gate oxide material 420 insulates the conductive material from the sidewalls of a bit contact pillar 410, the sidewalls of a cell contact pillars 415, and the surface of the semiconductor substrate 405 between the bit contact pillar 410 and the cell contact pillar 415. In some examples, forming the one or more word lines may include a patterning operation to form elongated word lines 215 that extend in a first horizontal direction (e.g., the word line direction).

As shown in FIG. 5D, the process 500 may include forming the dielectric material 425 above the one or more word lines 215. The dielectric material 425 may comprise, consist of, or consist essentially of silicon nitride, silicon oxide, or other insulating materials. Forming the dielectric material 425 may include depositing the dielectric material 425 to fill the one or more trenches using a deposition process, such as CVD. In some examples, the process 500 may include a planarization step, such as chemical mechanical planarization (CMP), to create a flat surface on the dielectric material 425, the bit contact pillars 410, and/or the cell contact pillars 415.

As shown in FIG. 5E, the process 500 may include forming one or more placeholder materials 505, such as a temporary dielectric and/or photoresist layer, on upper surfaces of the bit contact pillars 410, the cell contact pillars 415, and the dielectric material 425. These placeholder materials may protect underlying structures during subsequent processing steps and may be deposited using spin-coating or other suitable techniques.

The process 500 may include removing one or more portions of the placeholder material 505 to expose the upper surface 455 of the bit contact pillars 410 and/or the upper surface of the gate oxide material 420. This selective removal may be performed using a controlled etching process, such as reactive ion etching (RIE) or other dry etching techniques.

As shown in FIG. 5F, the process 500 may include removing one or more portions of the gate oxide material 420 to form one or more cavities. The one or more cavities may expose the upper sidewalls 445 of the bit contact pillar 410. Forming the one or more cavities may include performing an etching process selective to the gate oxide material, such as a wet etch process configured to remove the gate oxide material 420 while leaving other materials, such as the dielectric material 425 and/or the bit contact pillar 410, intact. Additionally, because the placeholder materials 505 may cover the cell contact pillar 415, the wet etch process may not remove gate oxide material 420 disposed on sidewalls of the cell contact pillar 415.

As shown in FIG. 5G, the process 500 may include forming a semiconductor material 510 in the one or more cavities. In some implementations, forming the semiconductor material 510 may include depositing the semiconductor material 510 epitaxially, such as by using a CVD process to grow the semiconductor material 510 on the upper sidewalls 445 and/or the upper surface 455 portions of the bit contact pillar 410. Alternatively, forming the semiconductor material 510 may include depositing polysilicon using a low-pressure CVD (LPCVD) process.

In some examples, forming the semiconductor material 510 may include doping the semiconductor material 510 with n-type dopants, such as phosphorus, and/or other semiconductor materials, such as carbon and/or germanium to form an alloy. For example, the process 500 may include doping the semiconductor material 510 as part of the deposition process (in-situ doping). Alternatively, the process 500 may include one or more or separate implantation steps post-deposition. Implantation steps may include using ion implantation techniques to introduce n-type dopants such as phosphorus, and/or other semiconductor materials, such as carbon and/or germanium to form an alloy.

Depositing the semiconductor material 510 may fill the one or more cavities, such that the semiconductor material 510 abuts sidewalls of the dielectric material 425 and abuts the upper sidewalls 445 of the bit contact pillar. Said another way, the dielectric material 425 may act as a physical stopping layer for the deposition process. Thus, the likelihood of surface defects on the semiconductor material 510 may be reduced.

In some examples, as shown in FIG. 5H, the process 500 may include patterning the semiconductor material 510 to form the socket structure 430. For example, the process 500 may include forming a photoresist material over the semiconductor material 510 and exposing the photoresist to radiation to create a pattern. The process 500 may include etching the exposed semiconductor material 510 using an anisotropic etching process such as RIE. In some examples, the process 500 may include additional manufacturing steps to configure the socket structure 430 as a landing area for a digit line.

As indicated above, the process steps described in connection with FIGS. 5A through 5H are provided as examples. Other examples may differ from what is described with respect to FIGS. 5A through 5H. The structure shown in FIGS. 5H may be equivalent to the structure 300 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

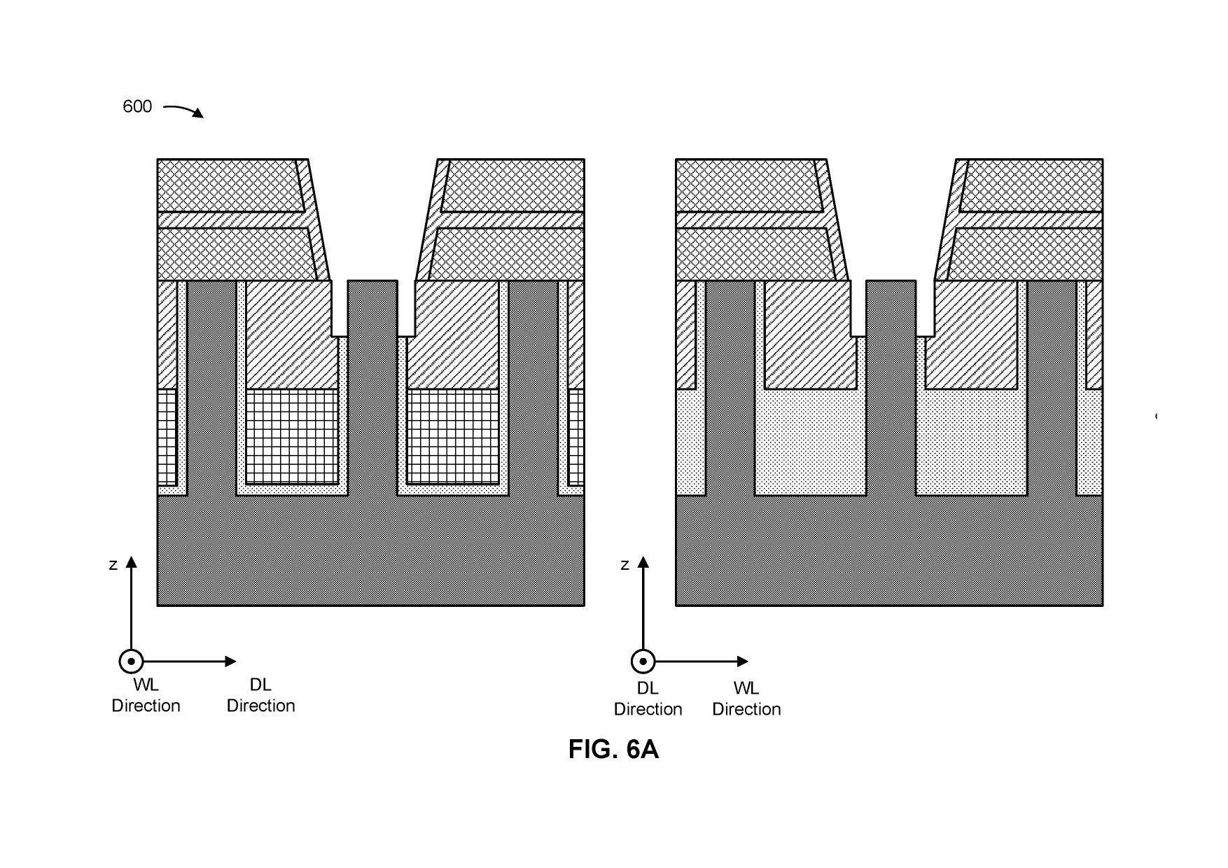

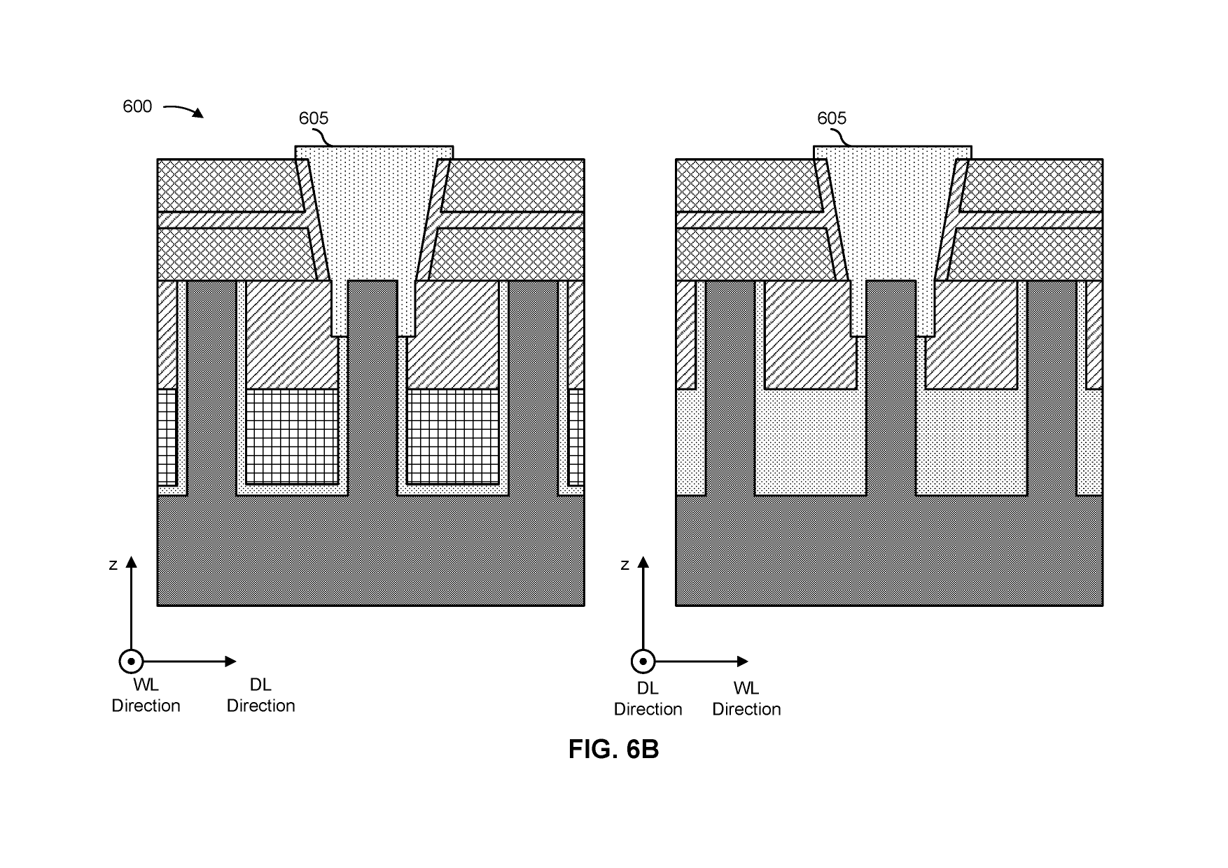

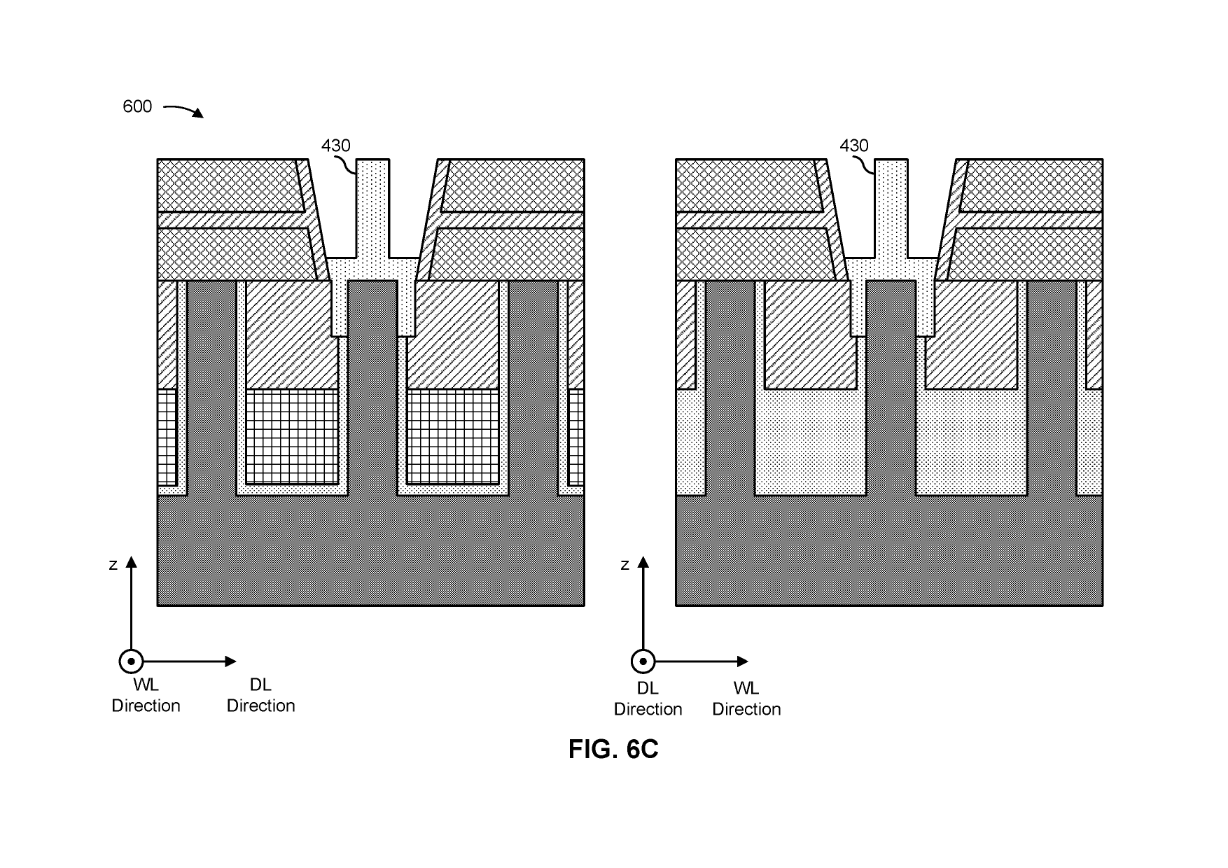

FIGS. 6A through 6C are diagrammatic views showing formation of the structure 400 at example process stages of an example process 600 of forming the structure 400. For example, FIGS. 6A through 6C may illustrate processing steps following the processing steps described in connection with FIG. 5F. In some implementations, the example process described below in connection with FIGS. 6A through 6C may correspond to the method 700 and/or one or more blocks of the method 700. However, the process described below is an example, and other example processes may be used to form the structure 400, an integrated assembly that includes the structure 400, and/or one or more parts of the structure 400 and/or the integrated assembly.

As shown in FIG. 6A, the process 600 may include removing one or more portions of the dielectric material 425 to expand the one or more cavities. Expanding the one or more cavities may include performing an additional etching process selective to the dielectric material 425, such as a wet etch process configured to remove the dielectric material 425 while leaving other materials, such as the gate oxide material 420 and/or the bit contact pillar 410, intact.

As shown in FIG. 6B, the process 600 may include forming a semiconductor material 605 in the one or more expanded cavities. In some implementations, forming the semiconductor material 605 may include depositing the semiconductor material 605 epitaxially, such as by using a CVD process to grow the semiconductor material 605 on the upper sidewalls 445 and/or the upper surface 455 portions of the bit contact pillar 410. Alternatively, forming the semiconductor material 605 may include depositing polysilicon using a low-pressure CVD (LPCVD) process.

In some examples, forming the semiconductor material 605 may include doping the semiconductor material 605 with n-type dopants. For example, the process 500 may include doping the semiconductor material 605 as part of the deposition process (in-situ doping). Alternatively, the process 600 may include one or more or separate implantation steps post-deposition. Implantation steps may include using ion implantation techniques to introduce n-type dopants.

Depositing the semiconductor material 605 may fill the one or more expanded cavities, such that the semiconductor material 605 abuts sidewalls of the dielectric material 425 and abuts the upper sidewalls 445 of the bit contact pillar. Said another way, the dielectric material 425 may act as a physical stopping layer for the deposition process.

In some examples, as shown in FIG. 6C, the process 600 may include patterning the semiconductor material 605 to form the socket structure 430. For example, the process 600 may include forming a photoresist material over the semiconductor material 605 and exposing the photoresist to radiation to create a pattern. The process 600 may include etching the exposed semiconductor material 605 using an anisotropic etching process such as RIE. In some examples, the process 600 may include additional manufacturing steps to configure the socket structure 430 as a landing area for a digit line. Because the one or more cavities may be expanded compared to the steps described with reference to FIGS. 5F through 5H, the overhangs 465 formed by the process 600 may be larger (e.g., thicker, wider in a horizontal direction) compared with the overhangs 465 formed by the process 500. This increased size may further improve the landing area of the socket structure 430 for a digit line, thus further reducing the likelihood of manufacturing defects.

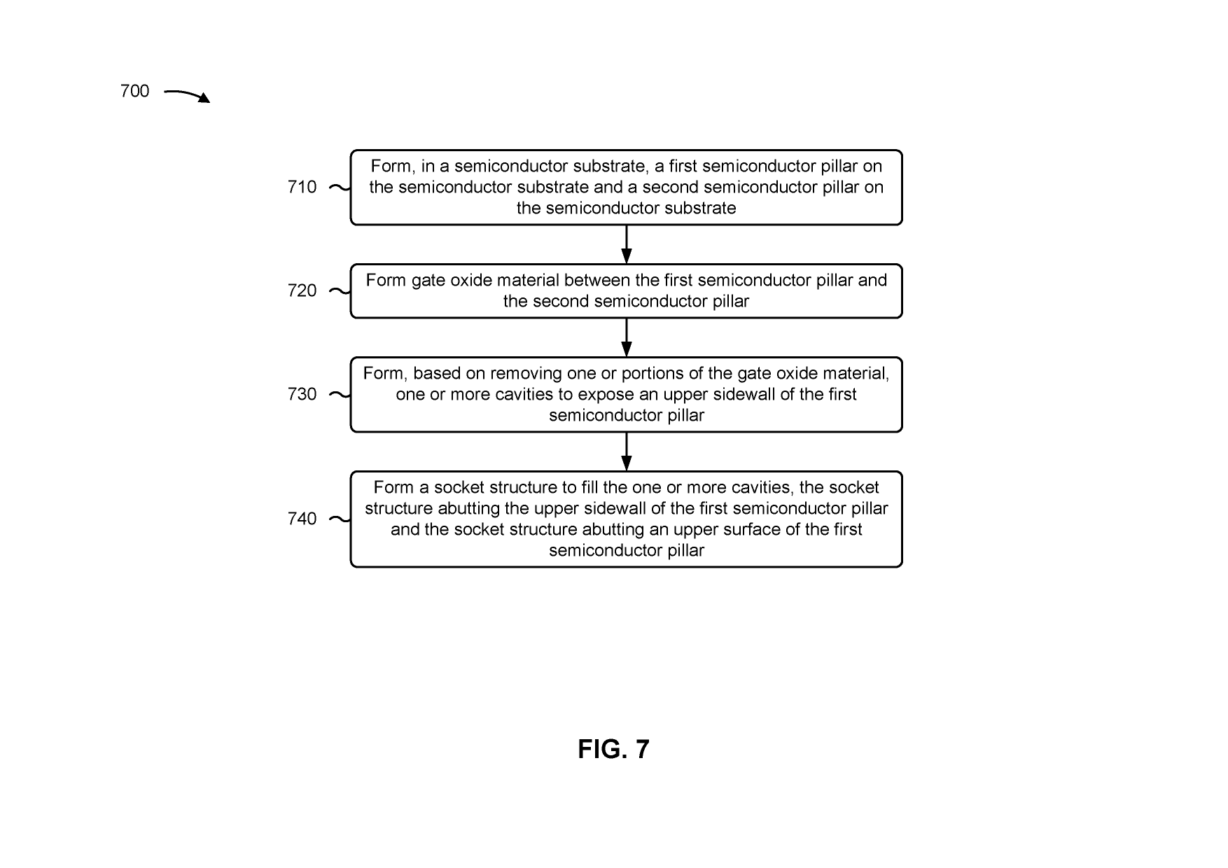

FIG. 7 is a flowchart of an example method 700 of forming an integrated assembly or memory device having improved bit contact landing area. In some implementations, one or more process blocks of FIG. 7 may be performed by various semiconductor manufacturing equipment.

As shown in FIG. 7, the method 700 may include forming, in a semiconductor substrate, a first semiconductor pillar on the semiconductor substrate and a second semiconductor pillar on the semiconductor substrate (block 710). As further shown in FIG. 7, the method 700 may include forming gate oxide material between the first semiconductor pillar and the second semiconductor pillar (block 720). As further shown in FIG. 7, the method 700 may include forming, based on removing one or more portions of the gate oxide material, one or more cavities to expose an upper sidewall of the first semiconductor pillar (block 730). As further shown in FIG. 7, the method 700 may include forming a socket structure to fill the one or more cavities, the socket structure abutting the upper sidewall of the first semiconductor pillar and the socket structure abutting an upper surface of the first semiconductor pillar (block 740).

The method 700 may include additional aspects, such as any single aspect or any combination of aspects described below and/or in connection with one or more other methods described elsewhere herein. In some implementations, an integrated assembly includes a first semiconductor pillar on a semiconductor substrate; a gate structure including a conductive portion and a cap portion on the conductive portion; gate oxide material, where a portion of the gate oxide material is between the first semiconductor pillar and the gate structure, and where the gate oxide material covers a side surface of the conductive portion and a lower side surface of the cap portion without covering an upper side surface of the cap portion; and a socket structure on the first semiconductor pillar, where a portion of the socket structure protrudes downwardly to be between the upper side surface of the cap portion and the first semiconductor pillar.

In a first aspect, the method 700 includes forming, before forming the one or more cavities, dielectric material between the first semiconductor pillar and the second semiconductor pillar.

In a second aspect, alone or in combination with the first aspect, the method 700 includes removing, before forming the socket structure, a portion of the dielectric material to expand the one or more cavities.

In a third aspect, alone or in combination with one or more of the first and second aspects, forming the socket structure comprises depositing epitaxial semiconductor material on exposed portions of the first semiconductor pillar to fill the one or more cavities.

In a fourth aspect, alone or in combination with one or more of the first through third aspects, forming the socket structure comprises depositing polycrystalline semiconductor material on exposed portions of the first semiconductor pillar to fill the one or more cavities.

In a fifth aspect, alone or in combination with one or more of the first through fourth aspects, forming the one or more cavities comprises performing a wet etching operation that is selective to the gate oxide material.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the structure 400, an integrated assembly that includes the structure 400, any part described herein of the structure 400, and/or any part described herein of an integrated assembly that includes the structure 400. For example, the method 700 may include forming one or more of the parts of the bit contact pillar 410, the cell contact pillar 415, the gate oxide material 420, and/or the socket structure 430.

In some implementations, an apparatus includes a bit contact pillar on a semiconductor substrate; a gate structure including a conductive portion and a cap portion on the conductive portion; gate oxide material, where a portion of the gate oxide material is between the first semiconductor pillar and the gate structure, and where the gate oxide material covers a side surface of the conductive portion and a lower side surface of the cap portion without covering an upper side surface of the cap portion; a word line aligned in a first direction through an isolation region, where the gate oxide material is between the word line and the bit contact pillar; and a bit contact structure having a concave profile, the bit contact structure on an upper portion of the bit contact pillar.

In some implementations, a method includes forming, in a semiconductor substrate, a first semiconductor pillar on the semiconductor substrate; forming a gate structure including a conductive portion and a cap portion on the conductive portion; forming gate oxide material, where a portion of the gate oxide material is between the first semiconductor pillar and the gate structure, and where the gate oxide material covers a side surface of the conductive portion and a lower side surface of the cap portion without covering an upper side surface of the cap portion; forming, based on removing one or more portions of the gate oxide material, one or more cavities to expose an upper sidewall of the first semiconductor pillar; and forming a socket structure on the first semiconductor pillar, where a portion of the socket structure protrudes downwardly to be between the upper side surface of the cap portion and the first semiconductor pillar.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a first semiconductor pillar on a semiconductor substrate;
a gate structure comprising a conductive portion and a cap portion on the conductive portion;
gate oxide material, wherein a portion of the gate oxide material is between the first semiconductor pillar and the gate structure, and wherein the gate oxide material covers a side surface of the conductive portion and a lower side surface of the cap portion without covering an upper side surface of the cap portion; and
a socket structure on the first semiconductor pillar, wherein a portion of the socket structure protrudes downwardly to be between the upper side surface of the cap portion and the first semiconductor pillar.

2. The integrated assembly of claim 1, wherein the socket structure comprises an n-type doped semiconductor material.

3. The integrated assembly of claim 1, wherein the socket structure comprises epitaxial semiconductor material.

4. The integrated assembly of claim 1, wherein the socket structure comprises polycrystalline semiconductor material.

5. The integrated assembly of claim 1, wherein the socket structure surrounds an upper portion of the first semiconductor pillar, the upper portion comprising an upper surface of the first semiconductor pillar and one or more upper sidewalls of the first semiconductor pillar.

6. The integrated assembly of claim 1, further comprising:
dielectric material in an isolation region between the first semiconductor pillar and a second semiconductor material, wherein the socket structure abuts a sidewall of the dielectric material.

7. The integrated assembly of claim 1, further comprising:
a word line aligned in a first direction through an isolation region, wherein the gate oxide material is between the word line and the first semiconductor pillar.

8. The integrated assembly of claim 7, wherein the word line is between the socket structure and the semiconductor substrate.

9. The integrated assembly of claim 7, wherein the socket structure is configured to couple to a digit line aligned in a second direction approximately perpendicular to the first direction.

10. The integrated assembly of claim 1, further comprising:
a contact structure on an upper surface of a second semiconductor pillar, wherein a first thickness of the contact structure is less than a second thickness of the socket structure.

11. The integrated assembly of claim 10, the socket structure is configured as a bit contact and the contact structure is configured as a cell contact.

12. An apparatus, comprising:
a bit contact pillar on a semiconductor substrate;
a gate structure comprising a conductive portion and a cap portion on the conductive portion;
gate oxide material, wherein a portion of the gate oxide material is between the bit contact pillar and the gate structure, and wherein the gate oxide material covers a side surface of the conductive portion and a lower side surface of the cap portion without covering an upper side surface of the cap portion;
a word line aligned in a first direction, wherein the gate oxide material is between the word line and the bit contact pillar; and
a bit contact structure having a concave profile, the bit contact structure on an upper portion of the bit contact pillar.

13. The apparatus of claim 12, wherein the bit contact structure is configured to couple to a digit line aligned in a second direction approximately perpendicular to the first direction.

14. The apparatus of claim 12, wherein the apparatus further comprises a cell contact pillar configured to couple to a capacitor of a memory cell of the apparatus.

15. A method, comprising:
forming, in a semiconductor substrate, a first semiconductor pillar on the semiconductor substrate;
forming a gate structure comprising a conductive portion and a cap portion on the conductive portion;
forming gate oxide material, wherein a portion of the gate oxide material is between the first semiconductor pillar and the gate structure, and wherein the gate oxide material covers a side surface of the conductive portion and a lower side surface of the cap portion without covering an upper side surface of the cap portion;
forming, based on removing one or more portions of the gate oxide material, one or more cavities to expose an upper sidewall of the first semiconductor pillar; and
forming a socket structure on the first semiconductor pillar, wherein a portion of the socket structure protrudes downwardly to be between the upper side surface of the cap portion and the first semiconductor pillar.

16. The method of claim 15, further comprising:
forming, before forming the one or more cavities, dielectric material between the first semiconductor pillar and a second semiconductor pillar.

17. The method of claim 16, further comprising:
removing, before forming the socket structure, a portion of the dielectric material to expand the one or more cavities.

18. The method of claim 15, wherein forming the socket structure comprises:
depositing epitaxial semiconductor material on exposed portions of the first semiconductor pillar to fill the one or more cavities.

19. The method of claim 15, wherein forming the socket structure comprises:
depositing polycrystalline semiconductor material on exposed portions of the first semiconductor pillar to fill the one or more cavities.

20. The method of claim 15, wherein forming the one or more cavities comprises:
performing a wet etching operation that is selective to the gate oxide material.
